(19) United States
(12) Patent Application Publication
(10) Pub. No.: US 2025/0244084 A1
(43) Pub. Date: Jul. 31, 2025

(54) FLUID FLAT TUBE HEAT DISSIPATION DEVICE

(71) Applicant: Jinlian Industry Hardware Co., Ltd., Zhuhai (CN)

(72) Inventor: Xiao Zeng, Zhuhai (CN)

(21) Appl. No.: 18/801,397

(22) Filed: Aug. 12, 2024

(30) Foreign Application Priority Data
Jan. 31, 2024 (CN) 2024202381488

(51) Int. Cl. F28F 1/02; F28D 21/00; F28F 1/04

(52) U.S. Cl. CPC F28F 1/025; F28F 1/04; F28D 2021/0028; F28F 2275/06

(57) ABSTRACT

A fluid flat tube heat dissipation device, comprising flat tube structure bodies, extending weldments and solder terminals; the flat tube structure bodies, extending weldments and solder terminals are integrated into a single unit by means of welding, and the flat tube structure bodies are connected to shunt components; a plurality of the flat tube structure bodies are spliced together and are welded by means of the extending weldments, and two outer ends of a plurality of spliced flat tube structure bodies are welded with the shunt components by means of the solder terminals. The invention belongs to the technical field of heat dissipation of industrial equipment, and specifically refers to a fluid flat tube heat dissipation device.

### 1. TECHNICAL FIELD

The invention belongs to the technical field of heat dissipation of industrial equipment, and specifically refers to a fluid flat tube heat dissipation device.

### 2. BACKGROUND ART

Fluid cooling technology refers to, under environment of high power progress driven by artificial intelligence, new energy and other computing power enhancement and that the traditional air cooling technology can not meet the need for heat dissipation and conductive cooling of high power chips in new technical conditions, utilizing copper, aluminum, steel, high-performance plastics, and other materials with high thermal conductivity and fluid medium to absorb heat generated by source of heat, which is then transmitted to the cooling mechanism via fluid flow channel structure, circular injection after being fully cooled down to achieve the purpose of rapid heat dissipation.

Shortcomings for prior art lies in that, for a large area of linear welding structure, in the installation, transportation, testing, application process of the material, the flat tube structure is prone to deformation, whether it is deformed by external forces or deformation caused by high pressure in the chamber, it will produce stress fatigue on the strength of the welded joints and lead to leakage phenomenon; once the leakage occurs, it will cause serious losses due to short circuit and burning out of server circuit board; and flat tube structure is characterized in projection or depression of welding solder residue in the welding process, which will not be able to ensure the contact area of the heat source and may affect the heat dissipation performance of the chip, thus affecting the heat dissipation efficiency.

### 3. SUMMARY OF THE INVENTION

In order to solve the above mentioned risk of welded joint leakage in long-strip welded line and feature of projection or depression of welding solder residue of traditional flat tube structure, which is not able to ensure the contact area of the heat source and may affect the heat dissipation performance, the invention provides a fluid flat tube heat dissipation device.

In order to realize the above functions, the technical solution provided by the invention is as follows: a fluid flat tube heat dissipation device, comprising flat tube structure bodies, extending weldments and solder terminals; the flat tube structure bodies, extending weldments and solder terminals are integrated into a single unit by means of welding, and the flat tube structure bodies are connected to shunt components; a plurality of the flat tube structure bodies are spliced together and are welded by means of the extending weldments, and two outer ends of a plurality of spliced flat tube structure bodies are welded with the shunt components by means of the solder terminals.

As a preferred technical solution of the invention, a seahorse head clearance portion is formed at each welding point of the flat tube structure body and the solder terminal.

As a preferred technical solution of the invention, the solder terminal is set in an L-shaped structure, and the extending weldment is set in a double-headed L-shaped structure.

As a preferred technical solution of the invention, the flat tube structure body is an integrally-formed structure.

As a preferred technical solution of the invention, said flat tube structure body is provided with a memory bank clearance portion.

Compared with the prior art, the invention has the following advantages:
1. The flat tube structure body is used for fluid heat dissipation, which completely avoids the problem of solder penetration and spreading in linear welding part, occupying the area inside the chamber and narrowing the cross-sectional area of the flow path, and the welding process is actually local welding, different from the overall heating of the traditional flat tube welding, which reduces the phenomenon of annealing softening after flat tube being heated at high temperatures, and avoids the problem in prior art that the material is prone to become soft, easily deformed and not easy to correct shape, and brittle failure at welding joints will occur if it is forced to correct shape; the welding process does not require the flat tube structure body to be clamped and shaped and completely avoids problem of unevenness of the heat source contact surface, which is conducive to ensuring and increasing the contact area of the heat source surface of the chip to ensure the conduction efficiency between heat dissipation heat source area and the heat dissipation conductor and can realizes instantaneous heat dissipation and cooling capacity in a faster and stronger manner, increasing the heat dissipation efficiency by 20% on the basis of original structure;
2. A plurality of the flat tube structure bodies are spliced together and are welded by means of the extending weldments, and two outer ends of a plurality of spliced flat tube structure bodies are welded with the shunt components by means of the solder terminals, splicing and welding methods can be combined and arranged according to heat dissipation environment of different products, the flat tube structure bodies and the solder terminals are in welded connection with the shunt, each single unit or the whole welded part has a very strong adaptive capacity, and can be applied to a plurality of continuous assembly welding function; due to the use of small end face area welding process, the welding area is reduced by more than 80% compared with prior art; and in the installation, transportation, testing, application environment, middle position, with the highest frequency of occurring deformation and leakage, achieved the state of connection with no welded joints, the strength of which is greatly enhanced and avoids the risk of leakage arising therefrom, the stability of welding quality being enhanced; in the actual using environment, it increases the life of the heat source heat dissipation module and fatigue resistance performance;
3. The simple design for technological process of flat tube structure bodies follows the principle of ergonomics and provides a strong guarantee in the realization of reliable and stable mass production; it can provide a full range of optimization programs according to the actual application scenarios to reduce costs and save space, etc., and it can adjust external dimensions, thickness, molding positions of the structure according to the actual application scenarios, so as to adapt to different needs of installation; it can also adjust the material, grade and state of the structure, such as: copper, stainless steel, aluminum, iron, non-metallic materials, etc., so as to meet the needs of customers for different equipment heat dissipation performances according to the actual application scenario.

### 4. BRIEF DESCRIPTION OF ACCOMPANY DRAWINGS

FIG. 1 shows an overall structural schematic diagram of a combined arrangement of three sets of flat tube structure bodies of a fluid flat tube heat dissipation device proposed in the invention;

FIG. 2 shows an overall structural schematic diagram of a combined arrangement of six sets of flat tube structure bodies via extending weldments of a fluid flat tube heat dissipation device proposed in the invention;

FIG. 3 shows an overall structural schematic diagram of a combined arrangement of nine sets of flat tube structure bodies via extending weldments of a fluid flat tube heat dissipation device proposed in the invention;

FIG. 4 shows an overall structural schematic diagram of a combined arrangement of twelve sets of flat tube structure bodies via extending weldments of a fluid flat tube heat dissipation device proposed in the invention;

FIG. 5 shows an overall structural schematic diagram of a plurality of combined forms of flat tube structure bodies of a fluid flat tube heat dissipation device proposed in the invention;

FIG. 6 shows an assembled state of use of a fluid flat tube heat dissipation device proposed in the invention.

Wherein: 1 flat tube structure body, 2 extending weldment, 3 solder terminal, 4 shunt component, 5 seahorse head clearance portion, 6 memory bank clearance portion.

### 5. SPECIFIC EMBODIMENT OF THE INVENTION

The technical scheme of the invention is further described clearly and detailedly hereinafter with reference to the drawings. Obviously, only partial embodiments of the invention are shown and the actual structure is not limited thereto. All other embodiments, which can be obtained by those skilled in the art without making any creative effort based on the embodiments in the present invention, shall all fall within the protective scope of the invention.

In the description of the embodiments of the invention, it should be noted that, if the terms “center”, “on”, “below”, “left”, “right”, “vertical”, “horizontal”, “inner”, “outer”, etc. indicate orientations or positional relationships based on the orientations or positional relationships shown in the drawings or the orientations or positional relationships that the products of the invention are usually placed in when used, the orientations or positional relationships are only used for convenience of describing the invention and simplifying the description, but the terms do not indicate or imply that the devices or elements indicated must have specific orientations, be constructed in specific orientations, and operate, and therefore, should not be construed as limiting the invention. Furthermore, the terms “first”, “second”, “third” and the like are used solely to distinguish one from another and are not to be construed as indicating or implying relative importance.

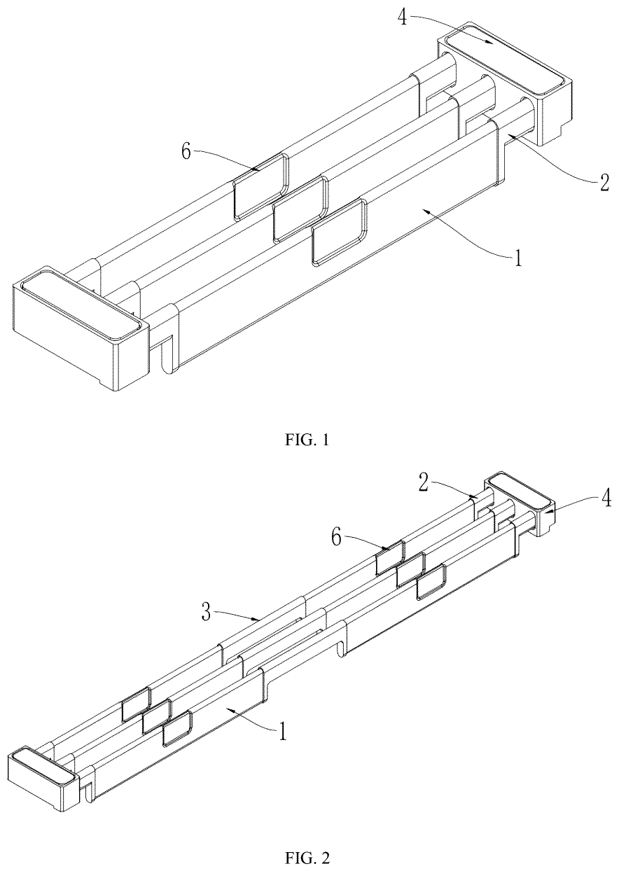

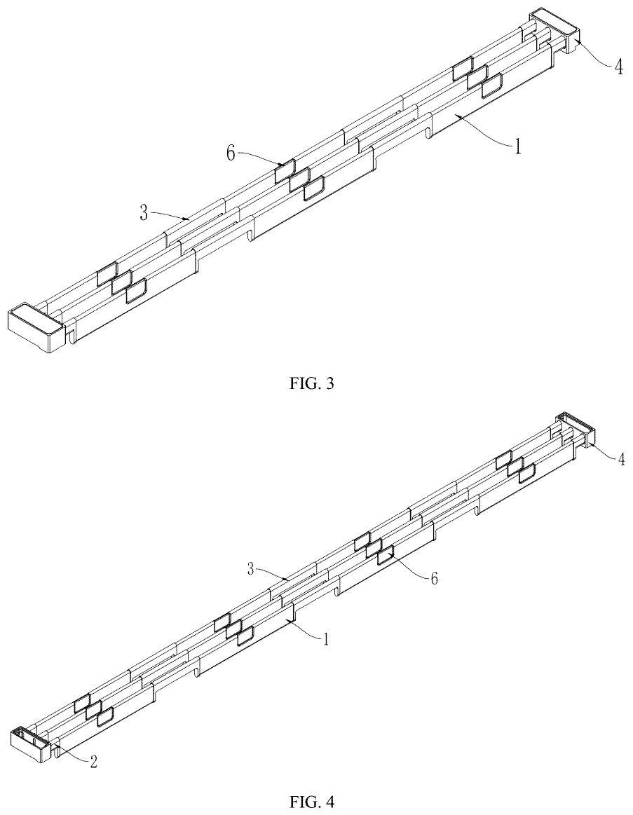

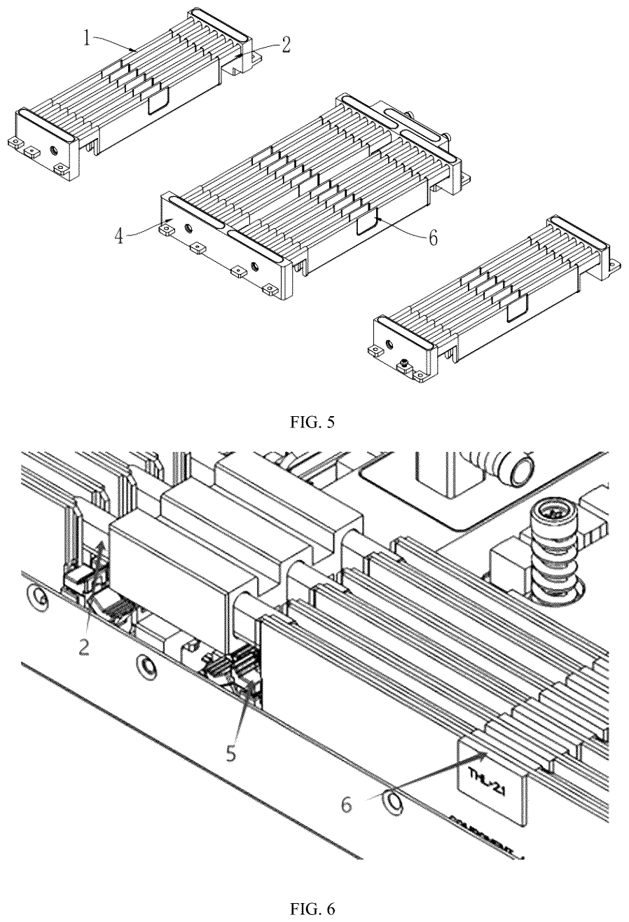

As shown from FIG. 1 to FIG. 6, the invention provides a fluid flat tube heat dissipation device, comprising flat tube structure bodies 1, extending weldments 2 and solder terminals 3; each flat tube structure body 1 is an integrally-formed structure, and the integrally-formed flat tube structure bodies are used for heat dissipation, which completely avoids the problem of solder penetration and spreading in linear welding part, occupying the area inside the chamber and narrowing the cross-sectional area of the flow path, and the welding process is actually local welding, different from the overall heating of the traditional flat tube welding, which reduces the phenomenon of annealing softening after flat tube being heated at high temperatures, and avoids the problem in prior art that the material is prone to become soft, easily deformed and not easy to correct shape, and brittle failure at welding joints will occur if it is forced to correct shape; the welding process does not require the flat tube structure body 1 to be clamped and shaped and completely avoids problem of unevenness of the heat source contact surface, which is conducive to ensuring and increasing the contact area of the heat source surface of the chip to ensure the dissipation performance of the chip, increasing the heat dissipation efficiency by 20% on the basis of original structure; the flat tube structure body 1 is provided with a memory bank clearance portion, which can be adaptively designed to form a clearance feature according to the change of environmental conditions, and the processing is easy and convenient, with excellent consistency to meet the actual assembly requirements. the solder terminal 3 is set in an L-shaped structure, and the extending weldment 2 is set in a double-headed L-shaped structure.

### Embodiment 1

The flat tube structure bodies 1 are used solely.

### Embodiment 2

As shown from FIG. 1 to FIG. 6, flat tube structure bodies 1, extending weldments 2 and solder terminals 3 are integrated into a single unit by means of welding, and the flat tube structure bodies 1 are connected to shunt components 4; a plurality of the flat tube structure bodies 1 are spliced together and are welded by means of the extending weldments 2, and two outer ends of a plurality of spliced flat tube structure bodies 1 are welded with the shunt components 4 by means of the solder terminals 3; splicing and welding methods can be combined and arranged according to heat dissipation environment of different products, the flat tube structure bodies 1 and the solder terminals 3 are in welded connection with the shunt, each single unit or the whole welded part has a very strong adaptive capacity, and can be applied to a plurality of continuous assembly welding function; due to the use of small end face area welding process, the welding area is reduced by more than 80% compared with prior art; and in the installation, transportation, testing, application environment, middle position, with the highest frequency of occurring deformation and leakage, achieved the state of connection with no welded joints, the strength of which is greatly enhanced and avoids the risk of leakage arising therefrom; a seahorse head clearance portion 5 is formed at each welding point of the flat tube structure body 1 and the solder terminal 3.

The invention and its embodiments have been described above, but the description is not limited thereto; only one embodiment of the invention is shown in the drawings, and the actual structure is not limited thereto. In general, it is to be understood by those skilled in the art that non-creative design of structural forms and embodiments that are similar to the technical solutions without departing from the spirit of the invention shall all fall within the protective scope of the invention.

1. A fluid flat tube heat dissipation device, comprising flat tube structure bodies, extending weldments and solder terminals; the flat tube structure bodies, extending weldments and solder terminals are integrated into a single unit by means of welding, and the flat tube structure bodies are connected to shunt components; a plurality of the flat tube structure bodies are spliced together and are welded by means of the extending weldments, and two outer ends of a plurality of spliced flat tube structure bodies are welded with the shunt components by means of the solder terminals.

2. The fluid flat tube heat dissipation device of claim 1, wherein a seahorse head clearance portion is formed at each welding point of the flat tube structure body and the solder terminal.

3. The fluid flat tube heat dissipation device of claim 1, wherein the solder terminal is set in an L-shaped structure, and the extending weldment is set in a double-headed L-shaped structure.

4. The fluid flat tube heat dissipation device of claim 1, wherein the flat tube structure body is an integrally-formed structure.

5. The fluid flat tube heat dissipation device of claim 1, wherein said flat tube structure body is provided with a memory bank clearance portion.
